(19) United States
(12) Patent Application Publication
(10) Pub. No.: US 2014/0357092 A1
(43) Pub. Date: Dec. 4, 2014

(54) CHAMBER WALL OF A PLASMA PROCESSING APPARATUS INCLUDING A FLOWING PROTECTIVE LIQUID LAYER

(71) Applicant: Lam Research Corporation, Fremont, CA (US)

(72) Inventor: Harmeet Singh, Fremont, CA (US)

(21) Appl. No.: 13/909,349

(22) Filed: Jun. 4, 2013

(51) Int. Cl. H01L 21/67; H01L 21/268

(52) U.S. Cl. CPC H01L 21/67069; H01L 21/67017; H01L 21/268
USPC 438/798; 156/345.48; 118/723 I; 156/345.41; 156/345.1; 118/723 MW; 118/723 R; 118/50; 137/1

(57) ABSTRACT

A semiconductor plasma processing apparatus includes a vacuum chamber in which semiconductor substrates are processed, a process gas source in fluid communication with the vacuum chamber for supplying a process gas into the vacuum chamber, and an RF energy source adapted to energize the process gas into the plasma state in the vacuum chamber. The apparatus can also include a chamber wall wherein the chamber wall includes a means for supplying a plasma compatible liquid to a plasma exposed surface thereof wherein the plasma compatible liquid flows over the plasma exposed surface thereby forming a flowing protective liquid layer thereon. A liquid supply delivers the plasma compatible liquid to the chamber wall.

### FIELD OF THE INVENTION

The present invention relates to a chamber wall of a vacuum chamber of a plasma processing apparatus. More specifically the invention relates to a chamber wall which includes a liquid flowing over a plasma exposed surface thereof wherein the liquid forms a flowing protective liquid layer thereon.

### BACKGROUND

In the field of semiconductor material processing, semiconductor plasma processing apparatus including vacuum processing chambers are used, for example, for etching and deposition, such as plasma etching or plasma enhanced chemical vapor deposition (PECVD) of various materials on substrates. Some of these processes, which utilize corrosive and/or erosive process gases and/or plasma, cause residues to form on interior surfaces of the chamber which can lead to nonuniform substrate processing, and/or cause chamber component wear, and particle and/or metal contamination of substrates processed in the chamber. Accordingly, it is desirable that interior surfaces of the chamber reduce the formation of residues, as well as be resistant to corrosion and/or erosion when exposed to such gases and plasma.

### SUMMARY

Disclosed herein is a semiconductor plasma processing apparatus which includes a vacuum chamber in which semiconductor substrates are processed, a process gas source in fluid communication with the vacuum chamber for supplying a process gas into the vacuum chamber, and an RF energy source adapted to energize the process gas into the plasma state in the vacuum chamber. The apparatus can also include a chamber wall wherein the chamber wall includes a means for supplying a plasma compatible liquid to a plasma exposed surface thereof wherein the plasma compatible liquid flows over the plasma exposed surface so as to form a flowing protective liquid layer thereon, and a liquid supply which delivers the plasma compatible liquid to the component.

Also disclosed herein is a method of forming a flowing protective liquid layer on a plasma exposed surface of a chamber wall in a plasma processing apparatus while processing a semiconductor substrate in a vacuum chamber. The method comprises supplying plasma compatible liquid from a liquid supply to a portion of the chamber wall and flowing the liquid over the plasma exposed surface of the chamber wall to form a flowing protective liquid layer on the plasma exposed surface thereof while plasma processing the semiconductor substrate in the vacuum chamber.

### BRIEF DESCRIPTION OF THE DRAWING FIGURES

FIGS. 1A and 1B each illustrate an embodiment of an inductively coupled plasma processing apparatus wherein embodiments presented herein may be practiced.

FIG. 2A illustrates an embodiment of a plasma processing apparatus wherein embodiments presented herein may be practiced. FIG. 2B illustrates an embodiment of a plasma processing apparatus wherein embodiments presented herein may be practiced. FIG. 2C illustrates a plasma exposed surface wherein embodiments presented herein may be practiced. FIG. 2D illustrates an embodiment of a plasma processing apparatus wherein embodiments presented herein may be practiced. FIG. 2E illustrates a plasma exposed surface wherein embodiments presented herein may be practiced.

FIG. 3 illustrates a schematic for a liquid delivery assembly wherein embodiments presented herein may be practiced.

### DETAILED DESCRIPTION

The manufacturing of the integrated circuit devices includes the use of plasma processing apparatuses. A plasma processing apparatus can include a vacuum chamber, and may be configured to perform semiconductor processing steps such as etching selected layers of a semiconductor substrate or depositing material upon a surface of a semiconductor substrate.

A plasma etching process may contain several steps in which elements of pressure, process gas, and power are combined in order to produce excited chemical species within the vacuum chamber. The excited chemical species of the etchant gas mixture, otherwise known as a plasma, contain radicals, ions, and neutrals which interact to varying degrees with exposed areas on the substrate, that is areas which are not covered and protected by a hardmask or photoresist. The interaction of elements of the plasma with the exposed material of the substrate effectively removes material in the uncovered region. The use of bias voltage provides directionality of ions accelerated toward the surface, thus providing substantial anisotropic etching. Features such as via holes and trenches can be formed in a complex stack of layers on the substrate using anisotropic etching in which sidewalls of the features can be protected from etching reaction by a passivation layer formed thereon. The etch gas typically contains a halogen containing gas for chemical etching and a polymer and/or an oxygen containing gas for passivation. The passivation layer can be polymer based or an oxide film containing silicon oxide (SiOₓ-based film) formed by deposition on or oxidation of the feature sidewalls.

Deposition processes can include atomic layer deposition or plasma enhanced chemical vapor deposition wherein dielectric or conductive films are deposited on the substrate. In plasma enhanced deposition, deposited species are formed after plasma is generated as a result of chemical reactions between gaseous reactants at elevated temperatures in the vicinity of the substrate wherein dielectric or conductive films are formed.

One challenge facing designers of plasma processing apparatuses is that the plasma processing conditions can create significant ion bombardment of surfaces of a vacuum chamber that are exposed to the plasma. This ion bombardment, combined with plasma chemistries and/or etch byproducts, can produce significant erosion, corrosion and corrosion-erosion of the plasma-exposed surfaces of the vacuum chamber. As a result, surface materials are removed by physical and/or chemical attack, including erosion, corrosion and/or corrosion-erosion. This attack causes problems including short part lifetimes, increased part costs, particulate contamination, on-substrate transition metal contamination, and process drift.

Another challenge facing designers of plasma processing apparatuses is that species generated in the plasma can lead to the formation of residue on interior surfaces of the vacuum chamber such as plasma exposed surfaces of chamber walls. For example, during an etching process, reactive species are generated in the plasma wherein the reactive species diffuse to the surface of the material (i.e. a film) being etched. The reactive species are adsorbed on the surface of the material being etched wherein a chemical reaction occurs resulting in the formation of etch byproducts. The etch byproducts are released from the surface of the material being etched wherein the byproducts can be deposited on the inner surfaces of the vacuum chamber. Thus, over time the inner surfaces of the chamber can build up a layer of etch byproducts (residue) that may contaminate a substrate being processed, cause process drift, and/or lead to nonuniform processing of a substrate being processed. The etch byproducts which form the residue may be non-volatile species released from films and chamber components containing materials such as Al, Cu, Mn, Mg, Ca, Ba, Fe, Co, Ni, Mn, In, Ta, Ti, Ge, As, Y, Pt, and Zr.

Embodiments disclosed herein provide chamber walls which include a flowing protective liquid layer on a surface thereof wherein a portion of the surface is a plasma exposed surface. As used herein, a “plasma exposed surface” includes one or more plasma exposed surfaces, as well as a surface wherein only a portion of the surface is plasma exposed. Further, “plasma exposed surface” as used herein includes surfaces which are exposed to process gases which are used during plasma etching processes.

The flowing protective liquid layer is formed from a plasma compatible liquid which is supplied from a liquid supply to a surface of the chamber wall. As used herein, “liquid” includes one or more liquids. The means for supplying the liquid to a surface of the chamber wall can include supplying the liquid through feed passages in the chamber wall. The feed passages in the chamber wall which supply the liquid can be pores of a porous ceramic material, or alternatively, holes formed in the chamber wall. The feed passages are preferably in fluid communication with a distribution channel wherein the distribution channel supplies the liquid to the feed passages. In an alternative embodiment, liquid can be supplied to the distribution channel wherein the liquid is configured to overflow from the distribution channel such that the distribution channel may supply the liquid to the plasma exposed surface of the chamber wall which flows thereover. The chamber wall is preferably formed from metal or ceramic materials including aluminum, aluminum alloy, aluminum oxide, alumina, stainless steel, silicon oxide, quartz, silicon, silicon carbide, YAG (yttrium aluminum garnet), yttrium oxide, yttrium fluoride, cerium oxide, aluminum nitride, graphite, or a combination thereof.

During plasma processing of a semiconductor substrate, the protective liquid layer is preferably continuously supplied to the plasma exposed surface of the chamber wall such that the liquid flows across the surface of the chamber wall during processing, thereby forming the flowing protective liquid layer. For example, a chamber wall can include a flowing protective liquid layer wherein the liquid forming the protective liquid layer is supplied to an upper portion of the chamber wall and flowed to a lower portion of the chamber wall, thus protecting the chamber wall from corrosion and/or erosion. Further, the liquid forming the flowing protective liquid layer can trap non-volatile etch byproducts therein. After trapping the non-volatile etch byproducts, the liquid can then be removed from the vacuum chamber and filtered, such that the formation of residue on interior surfaces of the vacuum chamber may be reduced, while allowing the liquid to be recycled. The liquid supplied to the plasma exposed surface of the chamber wall which forms the flowing protective liquid layer may also be circulated through a heat exchanger such that the liquid can maintain the temperature of the surface of the chamber wall at a desired temperature.

The flowing protective liquid layer is preferably formed from one or more ionic fluids. The liquid is a high purity plasma compatible liquid, and can be a flowable oxide precursor and/or a silicone based liquid (oils). Preferably the liquid has a low vapor pressure, such as a vapor pressure less than about 10⁻⁶ torrat about 20° C. The liquid can also be a perfluoropolyether. For example, liquids forming the protective liquid layer can be phenylmethyl siloxane, dimethyl cyclosiloxane, tetramethyl tetraphenyl trisiloxane, pentaphenyl trimethyl trisiloxane, 1-ethyl-3-methylimidazolium his {(trifluoromethyl)sul-fonyl}amide, 1-octyl-3-methylimidazolium his (trifluoromethanesulfonyl)imide, 1-butyl-3-methylimidazolium dicyanamide, hydrofluoroethylene, tetrafluoroethylene, perfluorotrimethyleneoxide, 1-ethyl-3-methylimidazolium chloride, 1-ethyl-3-methylimidazolium dicyanamide, 1-butyl-3,5-dimethylpyridinium bromide, 1-Butyl-3-methylimidazolium hexafluorophosphate, 1-Butyl-3-methylimidazolium hydrogen sulfate, 1-Butyl-3-methylimidazolium iodide, 1-Butyl-3-methylimidazolium methanesulfonate, 1-Butyl-3-methyl-imidazolium methyl carbonate, 1-Butyl-3-methylimidazolium methyl sulfate, 1-Butyl-3-methylimidazolium nitrate, 1-Butyl-3-methylimidazolium octyl sulfate, 1-Butyl-3-methylimidazolium tetrachloroaluminate, 1-Butyl-3-methylimidazolium tetrafluoroborate, 1-Butyl-3-methylimidazolium tetrafluoroborate, 1-Butyl-3-methylimidazolium thiocyanate, 1-Butyl-3-methylimidazolium tosylate, 1-Butyl-3-methylimidazolium trifluoroacetate, 1-Butyl-3-methylimidazolium trifluoromethanesulfonate, 1-(3-Cyanopropyl)-3-methylimidazolium bis(trifluoromethylsulfonyl)amide, 1-(3-Cyanopropyl)-3-methylimidazolium chloride, 1-(3-Cyanopropyl)-3-methylimidazolium dicyanamide, 1-Decyl-3-methylimidazolium chloride, 1-Decyl-3-methylimidazolium tetrafluoroborate, 1,3-Diethoxyimidazolium bis(trifluoromethylsulfonyl)imide, 1,3-Diethoxyimidazolium hexafluorophosphate, 1,3-Dihydroxyimidazolium bis(trifluoromethylsulfonyl)imide, 1,3-Dihydroxy-2-methylimidazolium bis(trifluoromethylsulfonyl)imide, 1,3-Dimethoxyimidazolium bis(trifluoromethyl-sulfonyl)imide, 1,3-Dimethoxyimidazolium hexafluorophosphate, 1,3-Dimethoxy-2-methylimidazolium bis(trifluoromethylsulfonyl)imide, 1,3-Dimethoxy-2-methylimidazolium hexafluorophosphate, 1,3-Dimethylimidazolium dimethyl phosphate, 1,3-Dimethylimidazolium methanesulfonate, 1,3-Dimethylimidazolium methyl sulfate, 1,2-Dimethyl-3-propylimidazolium bis(trifluoromethylsulfonyl)imide, 1,2-Dimethyl-3-propylimidazolium tris(trifluoromethylsulfonyl)methide, 1-Dodecyl-3-methylimidazolium iodide, 1-Ethyl-2,3-dimethylimidazolium tetrafluoroborate, 1-Ethyl-2,3-dimethylimidazolium chloride, 1-Ethyl-2,3-dimethylimidazolium ethyl sulfate, 1-Ethyl-2,3-dimethylimidazolium hexafluorophosphate, 1-Ethyl-2,3-dimethylimidazolium methyl carbonate, 1-Ethyl-3-methylimidazolium acetate, 1-Ethyl-3-methylimidazolium aminoacetate, 1-Ethyl-3-methylimidazolium (S)-2-aminopropionate, 1-Ethyl-3-methylimidazolium bis(pentafluoroethylsulfonyl)imide, 1-Ethyl-3-methylimidazolium bis(trifluoromethylsulfonyl)imide, 1-Ethyl-3-methylimidazolium bromide, 1-Ethyl-3-methylimidazolium chloride, 1-Ethyl-3-methylimidazolium dibutyl phosphate, 1-Ethyl-3-methylimidazolium diethyl phosphate, 1-Ethyl-3-methylimidazolium dimethyl phosphate, 1-Ethyl-3-methylimidazolium ethyl sulfate, 1-Ethyl-3-methylimidazolium hexafluorophosphate, 1-Ethyl-3-methylimidazolium hydrogen carbonate, 1-Ethyl-3-methylimidazolium hydrogencarbonate solution, 1-Ethyl-3-methylimidazolium hydrogen sulfate, 1-Ethyl-3-methylimidazolium hydroxide solution, 1-Ethyl-3-methylimidazolium iodide, 1-Ethyl-3-methylimidazolium L-(+)-lactate, 1-Ethyl-3-methylimidazolium methanesulfonate, 1-Ethyl-3-methyl-imidazolium methyl carbonate solution, 1-Ethyl-3-methylimidazolium methyl sulfate, 1-Ethyl-3-methylimidazolium nitrate, 1-Ethyl-3-methylimidazolium tetrachloroaluminate, 1-Ethyl-3-methylimidazolium tetrachloroaluminate, 1-Ethyl-3-methylimidazolium tetrafluoroborate, 1-Ethyl-3-methylimidazolium 1,1,2,2-tetrafluoroethanesulfonate, 1-Ethyl-3-methylimidazolium thiocyanate, 1-Ethyl-3-methylimidazolium tosylate, 1-Ethyl-3-methylimidazolium trifluoromethanesulfonate, 1-Hexyl-3-methylimidazolium bis(trifluormethylsulfonyl)imide, 1-Hexyl-3-methylimidazolium chloride, 1-Hexyl-3-methylimidazolium hexafluorophosphate, 1-Hexyl-3-methylimidazolium iodide, 1-Hexyl-3-methylimidazolium tetrafluoroborate, 1-Hexyl-3-methylimidazolium trifluoromethansulfonate, 1-(2-Hydroxyethyl)-3-methylimidazolium dicyanamide, 1-Methylimidazolium chloride, 1-Methylimidazolium hydrogen sulfate, 1-Methyl-3-octylimidazolium chloride, 1-Methyl-3-octylimidazolium hexafluorophosphate, 1-Methyl-3-octylimidazolium tetrafluoroborate, 1-Methyl-3-octylimidazolium trifluoromethanesulfonate, 1-Methyl-3-propylimidazolium iodide, 1-Methyl-3-propylimidazolium methyl carbonate solution, 1-Methyl-3-(3,3,4,4,5,5,6,6,7,7,8,8,8-tridecafluorooctyl)imidazolium hexafluorophosphate, 1-Methyl-3-vinylimidazolium methyl carbonate solution, 1,2,3-Trimethylimidazolium methyl sulfate, 1,2,3-Trimethylimidazolium trifluoromethanesulfonate purum, 1-Butyl-3-methylimidazolium acetate, 1-Butyl-3-methylimidazolium chloride, 1-Butyl-3-methylimidazolium hydrogen sulfate, 1-Butyl-3-methylimidazolium methanesulfonate, 1-Butyl-3-methylimidazolium methyl sulfate, 1-Butyl-3-methylimidazolium tetrafluoroborate, 1-Butyl-3-methylimidazolium thiocyanate, 1-Butyl-3-methylimidazolium trifluoromethanesulfonate, 1-Ethyl-2,3-dimethylimidazolium ethyl sulfate, 1-Ethyl-3-methylimidazolium acetate, 1-Ethyl-3-methylimidazolium chloride, 1-Ethyl-3-methylimidazolium dicyanamide, 1-Ethyl-3-methylimidazolium diethyl phosphate, 1-Ethyl-3-methylimidazolium ethyl sulfate, 1-Ethyl-3-methylimidazolium hydrogen sulfate, 1-Ethyl-3-methylimidazolium hydroxide solution, 1-Ethyl-3-methylimidazolium methanesulfonate, 1-Ethyl-3-methylimidazolium tetrachloroaluminate, 1-Ethyl-3-methylimidazolium tetrafluoroborate, 1-Ethyl-3-methylimidazolium thiocyanate, 1-Ethyl-3-methylimidazolium trifluoromethanesulfonate, 1-Methylimidazolium chloride, 1-Methylimidazolium hydrogen sulfate, α,α-[(Methyl-9-octadecenyliminio)di-2,1-ethanediyl]bis[ω-hydroxy-poly(oxy-1,2-ethanediye]methyl sulfate, 1,2,3-Trimethylimidazolium methyl sulfate, 1,2,4-Trimethylpyrazolium methylsulfate, Tetrabutylphosphonium methanesulfonate, Tetrabutylphosphonium tetrafluoroborate, Tetrabutylphosphonium p-toluenesulfonate, Tributylmethylphosphonium dibutyl phosphate, Tributylmethylphosphonium methyl carbonate solution, Tributylmethylphosphonium methyl sulfate, Triethylmethylphosphonium dibutyl phosphate, Trihexyltetradecylphosphonium bis(trifluoromethylsulfonyl)amide, Trihexyltetradecylphosphonium bis(2,4,4-trimethylpentyl)phosphinate, Trihexyltetradecylphosphonium bromide, Trihexyltetradecylphosphonium chloride, Trihexyltetradecylphosphonium decanoate, Trihexyltetradecylphosphonium dicyanamide, 3-(Triphenylphosphonio)propane-1-sulfonate, 3-(Triphenylphosphonio)propane-1-sulfonic acid tosylate, 1-Butyl-1-methylpiperidinium tetrafluoroborate, 1-Butyl-1-methylpiperidinium bis(trifluoromethylsulfonyl)imide, 1-Butyl-1-methylpiperidinium hexafluorophosphate, 4-Ethyl-4-methylmorpholinium methyl carbonate solution, 1,2,3-Tris(diethylamino)cyclopropenylium bis(trifluoromethanesulfonyl)imide, 1,2,3-Tris(diethylamino)cyclopropenylium dicyanamide, Cyclopropyldiphenylsulfonium tetrafluoroborate, Triethylsulfonium bis(trifluoromethylsulfonyl)imide, 1-Butyl-1-methylpyrrolidinium bis(trifluoromethylsulfonyl)imide, 1-Butyl-1-methylpyrrolidinium bromide, 1-Butyl-1-methylpyrrolidinium chloride, 1-Butyl-1-methylpyrrolidinium dicyanamide, 1-Butyl-1-methylpyrrolidinium hexafluorophosphate, 1-Butyl-1-methylpyrrolidinium iodide, 1-Butyl-1-methylpyrrolidinium methyl carbonate solution, 1-Butyl-1-methylpyrrolidinium tetrafluoroborate, 1-Butyl-1-methylpyrrolidinium trifluoromethanesulfonate, 1-Ethyl-1-methylpyrrolidinium bis(trifluoromethylsulfonyl)imide, 1-Ethyl-1-methylpyrrolidinium bromide, 1-Ethyl-1-methylpyrrolidinium hexafluorophosphate, 1-Ethyl-1-methylpyrrolidinium tetrafluoroborate, 1-Butyl-3-methylpyridinium bis(trifluormethylsulfonyl)imide, 1-Butyl-4-methylpyridinium hexafluorophosphate, 1-Butyl-4-methylpyridinium iodide, 1-Butyl-4-methylpyridinium tetrafluoroborate, 1-Butylpyridinium bromide, 1-(3-Cyanopropyl)pyridinium bis(trifluoromethylsulfonyl)imide, 1-(3-Cyanopropyl)pyridinium chloride, 1-Ethylpyridinium tetrafluorob orate, N-Ethylpyridinium bromide-d10,3-Methyl-1-propylpyridinium bis(trifluormethylsulfonyl)imide, 1,2,4-Trimethylpyrazolium methylsulfate, 1-Ethyl-3-methylimidazolium chloride, 1-Butyl-3-methylimidazolium chloride, 1-Ethyl-3-methyl imidazolium methanesulfonate, 1-Ethyl-3-methyl imidazolium ethylsulfate, 1-Ethyl-3-methyl imidazolium diethylphosphate, 1-Ethyl-3-methyl imidazolium dicyanamide, 1-Ethyl-3-methyl imidazolium acetate, Tris-(2-hydroxyethyl)-methylammonium methylsulfate, 1-Ethyl-3-methyl imidazolium thiocyanate, 1-Ethyl-3-methyl imidazolium tetrafluoroborate, 1-Ethyl-3-methyl imidazolium triflourmethanesulfonate, 1-Ethyl-3-methyl imidazolium bis(trifluormethanesulfonyl)imide, 1-Ethyl-3-methyl imidazolium methylcarbonate, 1-Butyl-3-methyl imidazolium methylcarbonate, Benzyldimethyltetradecylammonium chloride anhydrous, Benzyltrimethylammonium tribromide purum, Butyltrimethylammonium bis(trifluoromethylsulfonyl)imide, Diethylmethyl(2-methoxyethyl)ammonium bis(trifluoromethylsulfonyl)imide, Ethyldimethylpropylammonium bis(trifluoromethylsulfonyl)imide, 2-Hydroxyethyl-trimethylammonium L-(+)-lactate, Methyltrioctadecylammonium bromide, Methyl-trioctylammonium bis(trifluoromethylsulfonyl)imide, Methyl-trioctylammonium bis(trifluoromethylsulfonyl)imide, Methyltrioctylammonium hydrogen sulfate, Methyltrioctylammonium thiosalicylate, Tetrabutylammonium benzoate, Tetrabutylammonium bis-trifluoromethanesulfonimidate, Tetrabutylammonium heptadecafluorooctanesulfonate, Tetrabutylammonium hydroxide 30-hydrate, Tetrabutylammonium methanesulfonate purum, Tetrabutylammonium nitrite, Tetrabutylammonium nonafluorobutanesulfonate, Tetrabutylammonium succinimide, Tetrabutylammonium thiophenolate, Tetrabutylammonium tribromide purum, Tetrabutylammonium triiodide, Tetradodecylammonium bromide, Tetradodecylammonium chloride, Tetrahexadecylammonium bromide purum, Tetrahexylammonium bromide purum, Tetrahexylammonium hydrogensulfate, Tetrahexylammonium iodide, Tetrahexylammonium tetrafluoroborate, Tetrakis(decyl)ammonium bromide, Tetramethylammonium hydroxide pentahydrate, Tetraoctylammonium bromide purum, Tributylmethylammonium chloride, Tributylmethylammonium dibutyl phosphate, Tributylmethylammonium methyl carbonate, Tributylmethylammonium methyl sulfate, Tris(2-hydroxyethyl)methylammonium methylsulfate, Triethylmethylammonium dibutyl phosphate, Triethylmethylammonium methyl carbonate, Cholin acetate, 1-Allyl-3-methylimidazolium bis(trifluoromethylsulfonyl)imide, 1-Allyl-3-methylimidazolium bromide, 1-Allyl-3-methylimidazolium chloride, 1-Allyl-3-methylimidazolium dicyanamide, 1-Allyl-3-methylimidazolium iodide, 1-Benzyl-3-methylimidazolium chloride, 1-Benzyl-3-methylimidazolium hexafluorophosphate, 1-Benzyl-3-methylimidazolium tetrafluoroborate, 1,3-Bis(cyanomethyl)imidazolium bis(trifluoromethylsulfonyl)imide, 1,3-Bis(cyanomethyl)imidazolium chloride purum, 1-Butyl-2,3-dimethylimidazolium chloride, 1-Butyl-2,3-dimethylimidazolium hexafluorophosphate, 1-Butyl-2,3-dimethylimidazolium tetrafluoroborate, 4-(3-Butyl-1-imidazolio)-1-butanesulfonate, 4-(3-Butyl-1-imidazolio)-1-butanesulfonic acid triflate, 1-Butyl-3-methylimidazolium acetate, 1-Butyl-3-methylimidazolium bis(trifluoromethylsulfonyl)imide, 1-Butyl-3-methylimidazolium bromide, 1-Butyl-3-methylimidazolium chloride, 1-Butyl-3-methylimidazolium dibutyl phosphate, 1-Butyl-3-methylimidazolium hexafluoroantimonate, 1-Butyl-3-methylimidazolium hydrogen sulfate, 1-butyl-3-methylimidazolium hexafluorophosphate, and mixtures thereof. Preferably the plasma compatible liquid has a molecular weight of about 800 to 5,000 g/mol, and more preferably the molecular weight of the liquid or liquids is greater than about 1,000 g/mol.

The plasma compatible liquid is preferably stored in at least one liquid supply, wherein the liquid is configured to be supplied to a plasma exposed surface of the chamber wall, such as a plasma exposed surface of a chamber wall, to form a protective liquid layer thereon before and/or during processing of semiconductor substrates. The liquid is preferably continuously supplied to an upper portion of the chamber wall wherein the force of gravity causes the liquid to flow over the surface of the chamber wall to a lower portion thereof. Alternatively, the liquid can be supplied to the chamber wall wherein the chamber wall is configured to rotate such that the liquid flows over the surface of the chamber wall. The liquid which is supplied can be determined by a process recipe. For example, a liquid may be selected to be compatible with a specific processing step based on which process gases are selected for the specific processing step.

When exposed to plasma, the flowing protective liquid layer forms volatile by-products which can be removed from the vacuum chamber. In this manner, chamber walls formed from metallic material need not include a protective ceramic coating on a plasma exposed portion thereof. For example, a chamber wall which formerly included a ceramic outer coating on plasma exposed portions thereof, such as yttrium oxide outer coating, need not include the ceramic coating, and further, a chamber wall formerly made of silicon carbide material may now be formed from aluminum, which may reduce materials and machining costs of walls required for use in plasma processing apparatuses. The liquid forming the flowing protective liquid layer on a plasma exposed surface of the chamber wall additionally forms a liquid-plasma interface.

In an embodiment the liquid forming the flowing protective liquid layer is circulated to and from the vacuum chamber during plasma processing. The liquid can be supplied to a plasma exposed surface of the chamber wall, flowed over the surface of the chamber wall, and returned to the liquid supply, or in an alternate embodiment, the liquid can be supplied to a distribution channel of the chamber wall wherein the distribution channel is in fluid communication with a plasma exposed surface of the chamber wall. The liquid can be circulated through a heat exchanger thereby maintaining the plasma exposed surface of the chamber wall at a controlled temperature. In another preferred embodiment, the liquid may be circulated through a filter such that non-volatile etch byproducts as well as impurities in the liquid resulting from processing of semiconductor substrates are removed. Further, because liquid at the liquid-plasma interface becomes charged from plasma exposure during plasma processing processes, the liquid may be circulated through an electrical discharge conduit which removes charge built up in the liquid due to exposure to the plasma during plasma processing procedures.

The plasma compatible liquid is supplied to plasma exposed surfaces of the chamber wall wherein the liquid flows across the surface to form the flowing protective liquid layer thereon. Preferably, wetting forces between the plasma compatible liquid and the plasma exposed surface which receives the liquid overcome cohesive forces of the liquid which may cause the liquid to bead. The plasma exposed surface is preferably sloped or vertical such that the contact angle between the plasma exposed surface and the liquid as well as the surface tension and/or viscosity of the liquid causes the liquid to remain on the plasma exposed surface to form a flowing protective liquid layer, and not bead on the plasma exposed surface or drip therefrom. Preferably the angle of the sloped plasma exposed surface is greater than 45 degrees however in some cases, depending on the plasma compatible liquid, an angle of less than 45 degrees may be used. Additionally, the plasma exposed surface can include microgrooves and/or ribs wherein the microgrooves and/or ribs channel and distribute the liquid thereby forming a continuous protective liquid layer on the plasma exposed surface of the chamber wall.

Preferably, the plasma processing apparatus wherein embodiments disclosed herein may be practiced is an inductively coupled plasma processing apparatus, a capacitively coupled plasma processing apparatus, an electron cyclotron resonance plasma processing apparatus, a helicon wave plasma processing apparatus, or a microwave plasma processing apparatus. A Kiyo system by Lam Research Corporation may be used to practice embodiments disclosed herein.

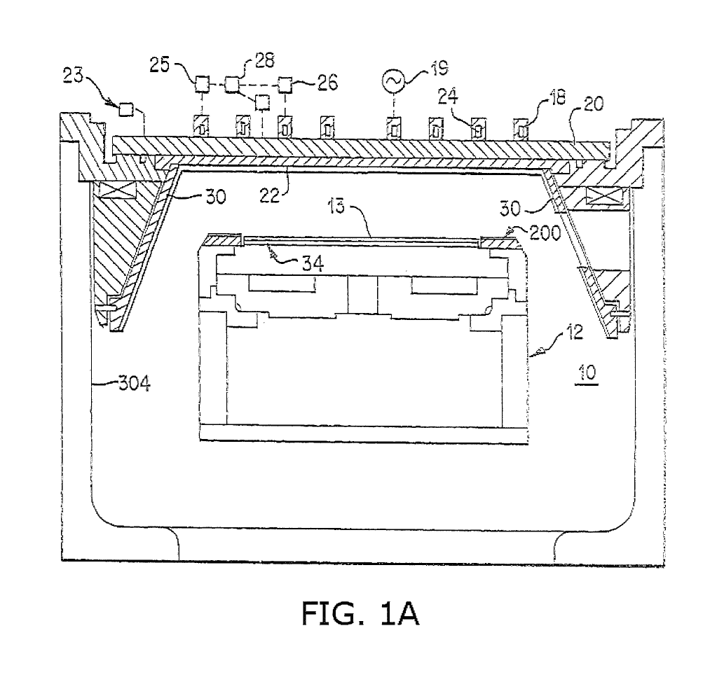

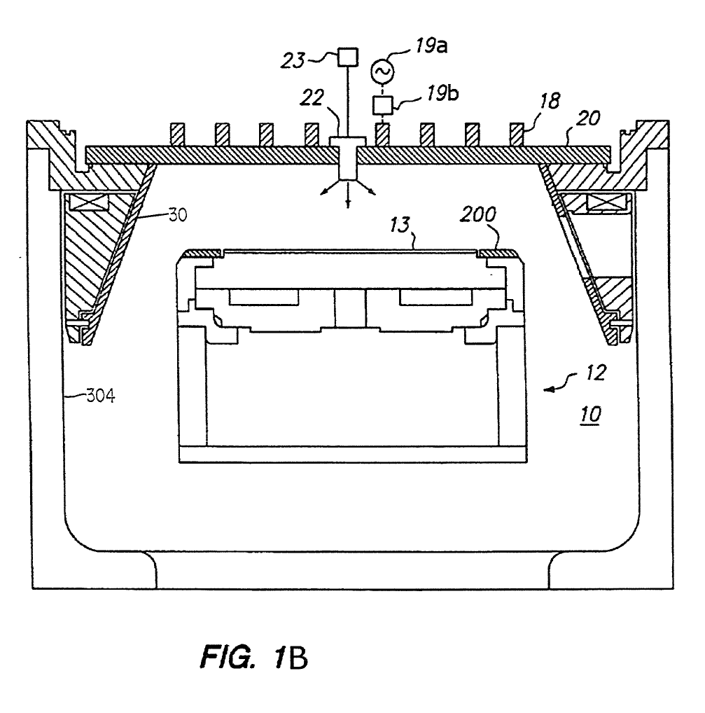

FIG. 1A illustrates a plasma apparatus which may be used in accordance with embodiments disclosed herein. The apparatus includes a vacuum chamber 10. A substrate support 12 includes an electrostatic chuck 34, which provides a clamping force and an RF bias to a substrate 13. The substrate 13 can be back-cooled using a heat transfer gas such as helium. An edge ring 200 confines plasma in a region above the substrate. A source of energy for maintaining a high density (e.g., 10⁹-10¹² ions/cm³) plasma in the chamber, such as an antenna 18 powered by a suitable RF source 19 to provide a high density plasma, is disposed at the top of the vacuum chamber 10. The vacuum chamber 10 includes a vacuum pumping apparatus for maintaining the interior of the chamber at a desired pressure (e.g., below 100 mTorr, typically 1-20 mTorr).

Dielectric window 20 is provided between the antenna 18 and the interior of the vacuum chamber 10 and forms a vacuum wall at the top of the vacuum chamber 10. A gas distribution plate 22 is optionally provided beneath window 20 and includes openings for delivering process gas from the gas supply 23 to the chamber 10. A chamber liner 30 which is preferably conical, extends from the gas distribution plate 22 and surrounds the substrate holder 12. The antenna 18 can be provided with a channel 24 through which a temperature control fluid is flowed via inlet and outlet conduit 25, 26. However, the antenna 18 and/or window 20 need not be cooled, or could be cooled by another suitable technique, such as by blowing gas over the antenna and window, passing a cooling fluid through or in heat transfer contact with the window and/or gas distribution plate, etc.

In operation, a substrate 13, such as a semiconductor wafer, is positioned on the substrate holder 12 and held in place by an electrostatic chuck 34. Other clamping means, however, such as a mechanical clamping mechanism can also be used. Additionally, helium back-cooling can be employed to improve heat transfer between the substrate and chuck. Process gas can be supplied to the vacuum processing chamber 10 by passing the process gas through a gap between the window 20 and the gas distribution plate 22. Suitable gas distribution plate arrangements (i.e., showerhead) arrangements are disclosed in commonly owned U.S. Pat. Nos. 5,824,605; 6,048,798; and 5,863,376, each of which is incorporated herein by reference in its entirety. A high density plasma is ignited in the space between the substrate and the window by supplying suitable RF power to the antenna 18.

In an alternate preferred embodiment, the inductively coupled plasma processing apparatus can include a gas injector which supplies process gas to an interior of the vacuum chamber. For example as illustrated in FIG. 1B, the inductively coupled plasma processing apparatus can include a vacuum chamber 10. The vacuum chamber 10 includes a substrate support 12 for supporting the substrate 13 in the interior of the vacuum chamber 10 wherein the substrate support 12 includes an edge ring 200. A dielectric window 20 forms a top wall of vacuum chamber 10. Process gases are injected to the interior of the vacuum chamber 10 through a gas injector 22. A gas supply 23 supplies process gases to the interior of the vacuum chamber 10 through gas injector 22.

Once process gases are introduced into the interior of vacuum chamber 10, they are energized into a plasma state by an antenna 18 supplying energy into the interior of vacuum chamber 10. Preferably, the antenna 18 is an external planar antenna powered by an RF source 19a and RF impedance matching circuitry 19b to inductively couple RF energy into vacuum chamber 10. However, in an alternate embodiment, the antenna 18 may be an external or embedded antenna which is nonplanar. An electromagnetic field generated by the application of RF power to planar antenna energizes the process gas to form a high-density plasma (e.g., 10⁹-10¹² ions/cm³) above substrate 120.

In FIGS. 1A and 1B, the plasma exposed surfaces of plasma processing apparatus chamber walls include a flowing protective liquid layer thereon. For example, such chamber walls can include at least the chamber liner 30 and vacuum chamber walls 304.

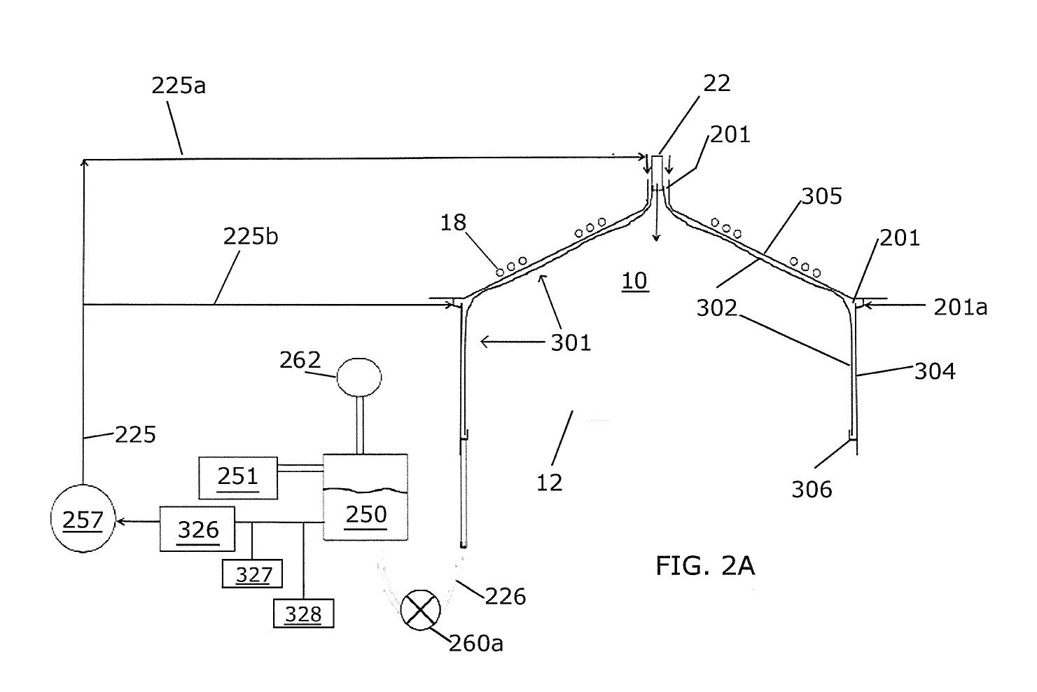

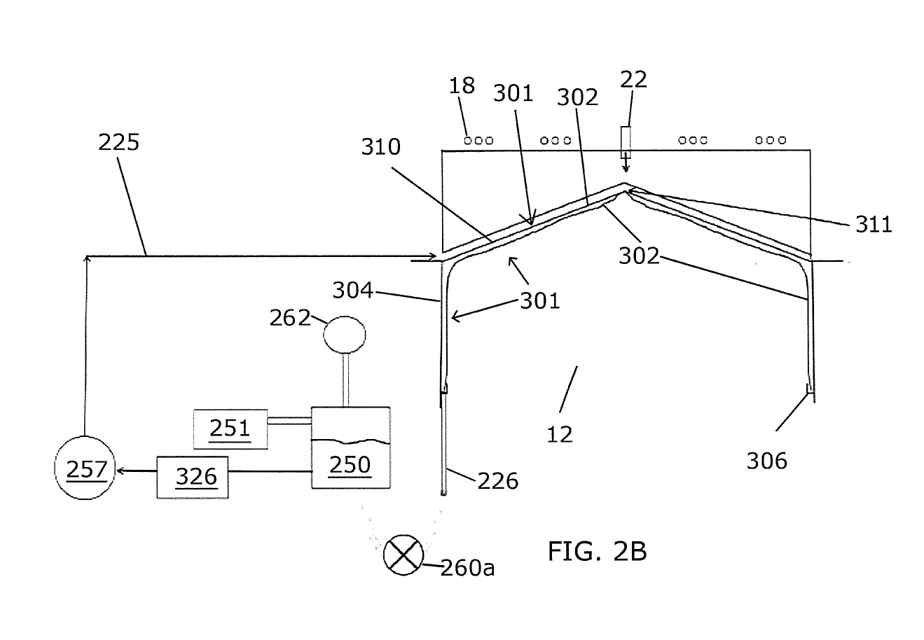

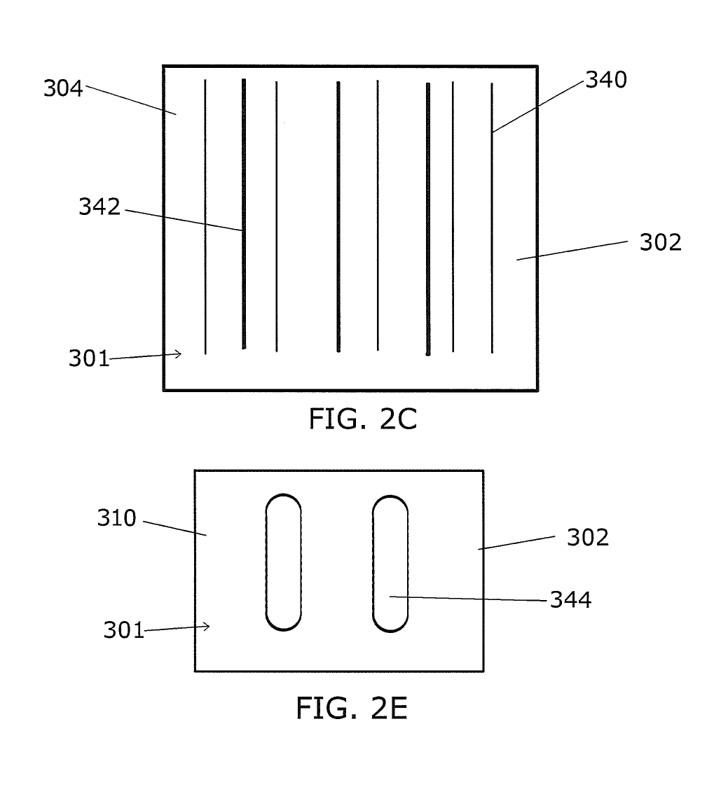

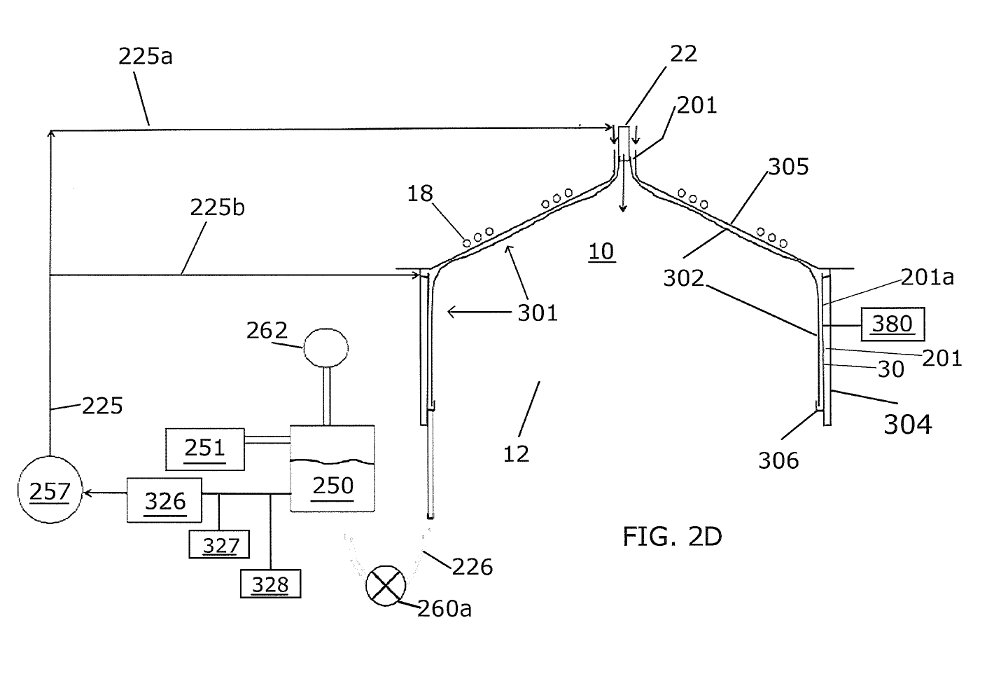

FIG. 2A illustrates a plasma processing apparatus which includes a liquid supply wherein embodiments of chamber walls including a flowing protective liquid layer as disclosed herein may be practiced. The plasma processing apparatus includes a vacuum chamber 10 which includes a substrate support 12 for supporting a substrate in the interior of the vacuum chamber 10. Process gases are injected into the interior of the vacuum chamber 10 through a gas injector 22 wherein once the process gases are introduced into the interior of vacuum chamber 10, they are energized into a plasma state by an antenna 18 which supplies energy into the interior of vacuum chamber 10. The vacuum chamber 10 is in fluid communication with the liquid supply 250 such that a plasma compatible liquid can be delivered to chamber walls in the vacuum chamber 10 through liquid inflow channel 225 and returned to the liquid supply 250 from the vacuum chamber 10 through liquid outflow channel 226. Plasma exposed surfaces of chamber walls, such as plasma exposed surfaces 301, within the vacuum chamber 10 preferably include a flowing protective liquid layer 302 thereon, wherein the flowing protective liquid layer is formed by supplying liquid to an upper portion of the plasma exposed surface of the chamber wall and flowing the liquid to a lower portion of the plasma exposed surface of the chamber wall.

Liquid is supplied to the plasma exposed surfaces 301 of the vacuum chamber 10 from the liquid supply 250 through the liquid inflow channel 225. In a preferred embodiment, the liquid inflow channel 225 can be divided into multiple inflow channels such that the liquid is delivered to separate plasma exposed surfaces 301 or separate portions of the same plasma exposed surface 301. For example, as illustrated in FIG. 2A, the liquid inflow channel 225 can be divided into liquid inflow channel 225a which delivers the liquid to an upper portion of an upper (top) chamber wall 305 (hereinafter ceiling), and liquid inflow channel 225a which delivers the liquid to an upper portion of a chamber sidewall 304. The sidewall 304 preferably includes a distribution channel 201 and feed passages 201a wherein the liquid can be delivered from the distribution channel 201 to the plasma exposed surface 301 of the sidewall 304 through feed passages 201a. Further, the liquid can be supplied to a distribution channel 201 in the ceiling 305 wherein the liquid in the distribution channel 201 of the ceiling 305 is configured to overflow from the distribution channel 201 to the plasma exposed surface 301 of the ceiling 305. In an alternate embodiment, the distribution channel 201 of the ceiling 305 and the plasma exposed surface 301 of the ceiling 305 may be in fluid communication via feed passages. Preferably the distribution channel 201 is an annular channel formed in the chamber sidewall 304 or the ceiling 305. The force of gravity forces the liquid to flow over the plasma exposed surface 301 wherein the liquid flows from respective upper portions of the sidewall 304 and the ceiling 305 to respective lower portions of the sidewall 304 and ceiling 305 such that a flowing protective liquid layer 302 is formed on the plasma exposed surface 301 of the sidewall 304 and the ceiling 305. Of course in an alternate embodiment, the liquid may be supplied to the ceiling 305 alone wherein the liquid is configured to flow from the ceiling 305 to the sidewall 304, or alternatively the sidewall 304 alone.

The liquid supply 250 can be connected to a gas supply 262 and a vacuum pump 251 such that the pressure of the liquid in the liquid supply 250 can be controlled. The gas in the gas supply 262 is preferably an inert gas such as Ar, He, N₂. An isolation valve 260a is operable to close the liquid outflow channel 226 of the vacuum chamber 10 such that the pressure differential between the liquid supply 250 and a vacuum pressure in the vacuum chamber 10 can force the liquid through liquid inflow channel 225 and a filter 326 towards plasma exposed surfaces 301 of the sidewall 304 and/or ceiling 305 such that the thickness of the liquid flowing over the plasma exposed surfaces 301 may be maintained at a predetermined thickness. Further, the liquid supply 250 can be connected to a liquid pump 257. The liquid pump 257 is preferably configured to pump the plasma compatible liquid towards the plasma exposed surfaces 301 of the sidewall 304 and/or ceiling 305 such that the thickness of the liquid on the plasma exposed surfaces 301 may be maintained at a predetermined thickness. Preferably the thickness of the liquid forming the flowing protective liquid layer 302 is maintained at about 1 to 5,000 microns. The filter 326 is configured to remove impurities and nonvolatile etch by-products from the liquid which may become trapped by the liquid during plasma processing of a semiconductor substrate. Additionally, the liquid can be circulated through a heat exchanger 327 thereby maintaining the plasma exposed surfaces 301 of the wall 304 and ceiling 305 at desired temperatures, as well as an electrical discharge conduit 328 which removes charge built up in the liquid due to exposure to the plasma during plasma processing procedures.

The vacuum chamber 10 preferably includes a liquid collection tray 306 at a lower portion thereof, wherein liquid flowing over plasma exposed surfaces 301 within the vacuum chamber 10 can be collected. Once collected, the liquid can be returned to the liquid supply 250 through liquid outflow channel 226 wherein the liquid can be filtered to remove harmful impurities and nonvolatile etch byproducts which have been trapped by the liquid forming the flowing protective liquid layer 302 during plasma processing before being resupplied to a plasma exposed surface 301 of the vacuum chamber 10. In an alternate embodiment, the liquid may be filtered before it is returned to the liquid supply 250.

In an embodiment, the plasma compatible liquid can be flowed over the plasma exposed surface of the chamber wall to a component adjacent the chamber wall. For example the liquid can be flowed over the plasma exposed surface of the ceiling 305 wherein the liquid is configured to flow from the ceiling 305 to the chamber wall 304. Alternatively, the liquid can be configured to flow from the ceiling 305 or chamber wall 304 to an adjacent component wherein the liquid is configured to pool on a plasma exposed surface of the adjacent component thereby forming a static protective liquid layer on the plasma exposed surface thereof. For example, the liquid can flow across a chamber liner wherein the liquid is configured to pool on a horizontal surface thereof.

FIG. 2B illustrates a plasma processing apparatus which includes a liquid supply wherein embodiments of chamber walls including a flowing protective liquid layer as disclosed herein may be practiced. In the embodiment as illustrated in FIG. 2B, the vacuum chamber 10 can include an internal wall 310 wherein plasma is maintained in the vacuum chamber 10 above the internal wall 310. The internal wall 310 includes openings, such as radial slots 344 (see FIG. 2E), wherein the openings allow plasma maintained above an upper plasma exposed surface of the internal wall 310 to diffuse below a lower plasma exposed surface of the internal wall 310 to plasma process a substrate supported on the substrate support 12. Preferably the space defined by openings in the internal wall 310 have an area equal to about 10 to 90% of the area of the internal wall 310. In a preferred embodiment, the plasma exposed surfaces of the internal wall 310 are sloped or vertical surfaces. Preferably the internal wall 310 is a faraday shield.

Liquid is supplied to a plasma exposed surface 301 of the internal wall 310 of the vacuum chamber 10 from the liquid supply 250 through the liquid inflow channel 225. In a preferred embodiment, the liquid is supplied to both the upper plasma exposed surface of the internal wall 310 and the lower plasma exposed surface of the internal wall 310 wherein the liquid forms a flowing protective liquid layer 302 on each of the upper plasma exposed surface and the lower plasma exposed surface. In a more preferred embodiment, the liquid is supplied to all exposed surfaces of the wall 310. The internal wall 310 can include a distribution channel 201 and feed passages therein, wherein the liquid can be delivered from the distribution channel 201 to the plasma exposed surfaces of the internal wall 310 through the feed passages. The feed passages can be configured to deliver the liquid to an upper portion of the wall 310 (a liquid flow starting point 311) wherein the force of gravity forces the liquid to flow over the plasma exposed surface from the upper portion of internal wall 310 to lower portions of the internal wall 310 such that a flowing protective liquid layer 302 is formed on the plasma exposed surface 301 of the internal wall 310. Alternatively, the liquid can be supplied to the distribution channel 201 wherein the liquid overflows from the distribution channel 201 at the liquid flow starting point 311 to the plasma exposed surface 301 of the wall 310. Preferably, the internal wall 310 is arranged such that the liquid flowing over the internal wall 310 can flow onto a plasma exposed surface 301 of the chamber sidewall 304 wherein the liquid can form a flowing protective liquid layer 302 thereon. In an alternate embodiment, the liquid may be independently supplied to the sidewall 304 as illustrated in FIG. 2A.

FIG. 2C illustrates an exemplary plasma exposed surface 301 which can include a flowing protective liquid layer 302 as described herein. The plasma compatible liquid is supplied to plasma exposed surface 301 of the chamber wall 304 wherein the liquid flows across the surface 301 to form the flowing protective liquid layer 302. Preferably, the plasma exposed surface 301 which receives the liquid is a sloped or vertical surface such that the surface tension of the liquid and the contact angle between the liquid and the plasma exposed surface 301 causes the liquid to form a flowing protective liquid layer 302, and not bead on the plasma exposed surface or drip therefrom. The plasma exposed surface 301 can include microgrooves 340 wherein the microgrooves 340 are configured to channel and distribute the liquid thereby forming a continuous flowing protective liquid layer 302. The plasma exposed surface 301 can also include ribs 341 which channel and distribute the liquid thereby forming a continuous flowing protective liquid layer 302.

FIG. 2D illustrates a plasma processing apparatus which includes a liquid supply wherein embodiments of chamber walls including means for a flowing protective liquid layer as disclosed herein may be practiced. The plasma processing apparatus includes a vacuum chamber 10 which includes a substrate support 12 for supporting a substrate in the interior of the vacuum chamber 10. Process gases are injected into the interior of the vacuum chamber 10 through a gas injector 22 wherein once the process gases are introduced into the interior of vacuum chamber 10, they are energized into a plasma state by an antenna 18 which supplies energy into the interior of vacuum chamber 10. The vacuum chamber 10 is in fluid communication with the liquid supply 250 wherein liquid inflow channel 225 and liquid outflow channel 226 are configured to circulate the plasma compatible liquid therebetween. The vacuum chamber 10 preferably includes a rotatable chamber liner 30, wherein the flowing protective liquid layer 302 is formed by supplying liquid to a portion of the plasma exposed surface 301 of the chamber liner 30 while rotating the chamber liner 30 such that the protective liquid flows over the plasma exposed surface 301 of the chamber liner 30. A drive mechanism 380 is configured to rotate the chamber liner 30 such that the rotation of the liner 30 causes the liquid to flow over the plasma exposed surface 301 thereof.

Liquid is supplied to the plasma exposed surfaces 301 of the vacuum chamber 10 from the liquid supply 250 through the liquid inflow channel 225. In a preferred embodiment, the liquid inflow channel 225 can be divided into multiple inflow channels such that the liquid is delivered to separate plasma exposed surfaces 301 or separate portions of the same plasma exposed surface 301. For example, the liquid inflow channel 225 can be divided into liquid inflow channel 225a which delivers the liquid to the ceiling 305, and liquid inflow channel 225a which delivers the liquid to the rotatable chamber liner 30. In an embodiment, the drive mechanism 380 can be configured to rotate the ceiling. The rotatable chamber liner 30 preferably includes a distribution channel 201 and feed passages 201a wherein the liquid can be delivered from the distribution channel 201 to the plasma exposed surface 301 of the rotatable chamber liner 30 through feed passages 201a. Further, the liquid can be supplied to a distribution channel 201 in the ceiling wherein the liquid in the distribution channel 201 of the ceiling 305 is configured to overflow from the distribution channel 201 to the plasma exposed surface 301 of the ceiling 305. In an alternate embodiment, the ceiling 305 and the plasma exposed surface 301 of the ceiling 305 may be in fluid communication via feed passages. Rotating the liner 30 and/or the ceiling 305 forces the liquid to flow over the plasma exposed surface 301 thereof such that a flowing protective liquid layer 302 is formed on the plasma exposed surface 301 of the rotatable chamber liner 30 and/or the rotatable ceiling 305. In an embodiment, the distribution channel 201 of the rotatable chamber liner 30 can be a channel which runs from a lower portion of the chamber liner 30 to an upper portion of the chamber liner 30. Alternatively, the distribution channel can be an annular channel at an upper portion of the chamber liner 30.

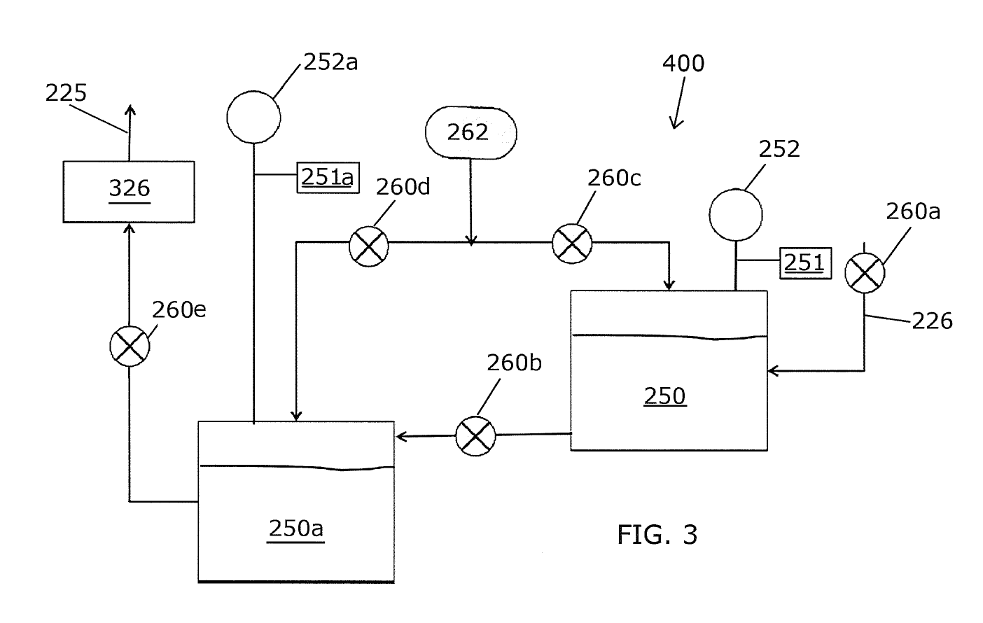

FIG. 3 illustrates an exemplary liquid delivery assembly 400 for delivering a liquid to a plasma processing chamber. The liquid delivery assembly 400 includes a first liquid supply 250. The first liquid supply 250 is in fluid communication with and can receive liquid from an outlet of the chamber via liquid outflow channel 226. The first liquid supply 250 is also in fluid communication with a first vacuum pump 251 and a gas supply 262 such that the pressure of the first liquid supply 250 can be controlled wherein a first manometer 252 measures the pressure in the first liquid supply 250. The liquid outflow channel 226 includes a first isolation valve 260a which is located between the first liquid supply 250 and the outlet of the chamber. The first isolation valve 260a allows the liquid which was collected by the liquid collection tray 306 in the vacuum chamber 10 to be returned to the first liquid supply 250 when in an open position, while blocking liquid flow to or from the outlet of the chamber when in a closed position. A second isolation valve 260b is located between the first liquid supply 250 and a second liquid supply 250a. When in a closed position, the second isolation valve 260b fluidly isolates the first liquid supply 250 from the second liquid supply 250a, and while in an open position the second isolation valve 260b allows the first liquid supply 250 to deliver liquid to the second liquid supply 250a. A third isolation valve 260c is located between the first liquid supply 250 and the gas supply 262. The third isolation valve 260c can be opened allowing gas to be delivered to the first liquid supply 250 wherein the delivered gas increases the pressure of the first liquid supply 250 which can thereby force the liquid towards the second liquid supply 250a when the second isolation valve 260b is in an open position. The first vacuum pump 251 can be operated to reduce the pressure in the first liquid supply 250 such that the pressure of the first liquid supply 250 and the pressure differential between the first liquid supply 250 and the second liquid supply 250a can be fine-tuned, and a desired amount of liquid can be forced towards or away from the second liquid supply 250a.

The second liquid supply 250a is further in fluid communication with the gas supply 262 and a second vacuum pump 251a such that the pressure of the second liquid supply 250a can be controlled wherein a second manometer 252 measures the pressure in the second liquid supply 250a. A fourth isolation valve 260d can be opened allowing gas to be delivered to the second liquid supply 250a wherein the delivered gas increases the pressure of the second liquid supply 250a which can thereby force the liquid towards the vacuum chamber when a fifth isolation valve 260e which is between the second liquid supply 250a and the vacuum chamber is in an open position. The second vacuum pump 251a can be operated to reduce the pressure in the second liquid supply 250a such that the pressure of the second liquid supply 250a and the pressure differential between the second liquid supply 250a and the vacuum chamber 10 can be fine-tuned, and a desired amount of liquid can be forced through the liquid inflow channel 225 towards or away from the vacuum chamber when the fifth isolation valve 260e is in an open position. Further, the pressure differential between the second liquid supply 250a and the vacuum chamber can force the liquid through a filter 326 included in the liquid inflow channel 225 such that impurities and/or nonvolatile etch byproducts trapped by the liquid can be removed. Alternatively, or in addition to the filter included in the liquid inflow channel 225, a filter can be located between the first liquid supply 250 and the second liquid supply 250a, or in the liquid outflow channel 226 between the first liquid supply 250 and the outlet of the vacuum chamber 10.

Preferably, the pressure in the first liquid supply 250 is preferably maintained at or below the processing pressure of the vacuum chamber during plasma processing procedures such that the liquid flows from the chamber to the first liquid supply 250. During part of the processing, the pressure in the second liquid supply 250a is maintained at the same pressure as the first liquid reservoir 250 while the second isolation valve 260b is in an open position such that the liquid can flow from the first liquid supply 250 to the second liquid supply 250a. The second isolation valve 260b can then be closed during part of the processing, wherein the fourth isolation valve 260d can be opened such that the gas supply 262 increases the pressure in the second liquid supply 250a and the liquid is pushed towards the vacuum chamber through the filter 326.

Additionally presented herein is a method of plasma processing a semiconductor substrate in a plasma processing apparatus, such as a plasma etching or deposition vacuum chamber, wherein the plasma processing apparatus includes a chamber wall with a protective liquid layer flowing over a plasma exposed surface thereof. The method includes supplying the plasma compatible liquid from the liquid supply to the chamber wall of the vacuum chamber, flowing the liquid over the plasma exposed surface of the chamber wall, supplying the process gas from the process gas source into the plasma processing chamber, applying RF energy to the process gas using the RF energy source to generate plasma in the plasma processing chamber, and plasma processing a semiconductor substrate in the plasma processing chamber.

While the chamber wall with the protective liquid layer on a plasma exposed surface thereof has been described in detail with reference to specific embodiments thereof, it will be apparent to those skilled in the art that various changes and modifications can be made, and equivalents employed, without departing from the scope of the appended claims.

What is claimed is:

1. A semiconductor plasma processing apparatus, comprising:
a vacuum chamber in which semiconductor substrates are processed;
a process gas source in fluid communication with the vacuum chamber for supplying a process gas into the vacuum chamber;
an RF energy source adapted to energize the process gas into the plasma state in the vacuum chamber;
a chamber wall wherein the chamber wall includes a means for supplying a plasma compatible liquid to a plasma exposed surface thereof wherein the liquid is supplied to a portion of the plasma exposed surface and flowed over the plasma exposed surface wherein the flowed plasma compatible liquid forms a flowing protective liquid layer thereon; and
a liquid supply which delivers the plasma compatible liquid to the chamber wall.

2. The semiconductor plasma processing apparatus of claim 1, wherein
(a) the means for supplying the liquid comprises liquid feed passages in the chamber wall, wherein the liquid feed passages are configured to distribute the liquid to an upper portion of the plasma exposed surface of the chamber wall such that the liquid flows to a lower portion thereof thereby forming the flowing protective liquid layer on the plasma exposed surface;
(b) the means for supplying the liquid comprises a distribution channel in the chamber wall wherein the distribution channel is in fluid communication with liquid feed passages in the chamber wall such that the distribution channel may supply the liquid through the liquid feed passages to the plasma exposed surface of the chamber wall;
(c) the means for supplying the liquid comprises a distribution channel in the chamber wall wherein the liquid is configured to overflow from the distribution channel such that the distribution channel may supply the liquid to the plasma exposed surface of the chamber wall;
(d) the means for supplying the liquid comprises a liquid inflow channel and a liquid outflow channel in the chamber wall wherein the liquid inflow channel and the liquid outflow channel are in fluid communication with a distribution channel in the chamber wall such that the liquid supplied to the chamber wall may be circulated to and from the chamber wall; and/or
(e) the means for supplying the liquid comprises liquid feed passages in the chamber wall, wherein the liquid feed passages are configured to distribute the liquid to a portion of the plasma exposed surface of the chamber wall wherein the wall is rotated such that the liquid flows over the plasma exposed surface thereof thereby forming the flowing protective liquid layer on the plasma exposed surface.

3. The semiconductor plasma processing apparatus of claim 2, wherein
(a) the chamber wall is a porous ceramic and the liquid feed passages are pores of the porous ceramic, and the pores are configured to deliver the liquid through the pores of the porous ceramic to the plasma exposed surface of the chamber wall; or
(b) the chamber wall is of a metallic material and the liquid feed passages are a pattern of capillary sized holes which are configured to deliver the liquid to the plasma exposed surface of the chamber wall.

4. The semiconductor plasma processing apparatus of claim 1, wherein
(a) the plasma exposed surface of the chamber wall is a sloped surface;
(b) the plasma exposed surface of the chamber wall is a vertical surface;
(c) the chamber wall is a chamber liner;
(d) the chamber wall includes a liquid collection tray;
(e) the chamber wall is formed from aluminum, aluminum alloy, aluminum oxide, alumina, stainless steel, silicon oxide, quartz, silicon, silicon carbide, YAG, yttrium oxide, yttrium fluoride, cerium oxide, aluminum nitride, graphite, or a combination thereof;
(f) the chamber wall includes microgrooves on the plasma exposed surface thereof wherein the microgrooves evenly distribute the liquid supplied to the plasma exposed surface such that the liquid forms a continuous flowing protective liquid layer; and/or
(g) the chamber wall includes ribs on the plasma exposed surface thereof wherein the ribs distribute the liquid supplied to the plasma exposed surface such that the liquid forms a continuos flowing protective liquid layer.

5. The semiconductor plasma processing apparatus of claim 1, wherein
(a) the apparatus is an inductively coupled plasma processing apparatus;
(b) the apparatus is a capacitively coupled plasma processing apparatus;
(c) the apparatus is an electron cyclotron resonance plasma processing apparatus;
(d) the apparatus is a helicon wave plasma processing apparatus; or
(e) the apparatus is a microwave plasma processing apparatus.

6. The semiconductor plasma processing apparatus of claim 1, wherein
(a) the plasma compatible liquid is stored in the liquid supply at a predetermined pressure, such that a pressure differential between the liquid supply and vacuum pressure in the vacuum chamber forces the liquid to flow in the liquid feed passages towards the plasma exposed surface of the chamber wall, wherein the predetermined pressure may be controlled such that the thickness of the liquid layer on the plasma exposed surface of the chamber wall may be maintained at a predetermined thickness; and/or
(b) the liquid supply includes a pump wherein the pump is configured to pump the plasma compatible liquid towards the plasma exposed surface of the chamber wall such that the thickness of the liquid on the plasma exposed surface of the chamber wall may be maintained at a predetermined thickness.

7. The semiconductor plasma processing apparatus of claim 1, wherein the chamber wall is a faraday shield wherein the faraday shield includes:
(a) a sloped plasma exposed surface;
(b) a vertical plasma exposed surface;
(c) an upper plasma exposed surface;
(d) a lower plasma exposed surface;
(b) the faraday shield includes microgrooves on the plasma exposed surface thereof wherein the microgrooves evenly distribute the liquid supplied to the plasma exposed surface of such that the liquid forms a continuous flowing protective liquid layer;
(c) the faraday shield includes a liquid collection tray; and/or
(d) the faraday shield includes ribs on the plasma exposed surface thereof wherein the ribs are distribute the liquid supplied to the plasma exposed surface such that the liquid forms a continuous flowing protective liquid layer.

8. The semiconductor plasma processing apparatus of claim 1, wherein
(a) the plasma compatible liquid is a flowable oxide precursor;
(b) the plasma compatible liquid is a silicone based liquid;
(c) the plasma compatible liquid is an ionic fluid;
(d) the plasma compatible liquid has a vapor pressure below about 10⁻⁶ torr at about 20° C.;
(e) the plasma compatible liquid is a perfluoropolyether;
(f) the plasma compatible liquid has a molecular weight of about 800 to 5,000 g/mol;
(g) the plasma compatible liquid has a molecular weight greater than about 1,000 g/mol;
(h) the plasma compatible liquid is selected from the group consisting of phenylmethyl siloxane,

9. A chamber wall including a flowing protective liquid layer on a plasma exposed surface thereof wherein the chamber wall includes a means for supplying a plasma compatible liquid to a plasma exposed surface thereof wherein the liquid is supplied to a portion of the plasma exposed surface and flowed over the plasma exposed surface wherein the flowed plasma compatible liquid forms a flowing protective liquid layer thereon.

10. A liquid delivery assembly for delivering a plasma compatible liquid to a vacuum chamber of a plasma processing apparatus comprising:
a first liquid supply wherein the first liquid supply is in fluid communication with an outlet of the vacuum chamber, a first vacuum pump, a second liquid supply, a gas supply, and a manometer, wherein a first isolation valve is located between the first liquid supply and the outlet of the chamber, a second isolation valve is located between the first liquid supply and the second liquid supply, and a third isolation valve is located between the first liquid supply and the gas supply;
wherein the second liquid supply is in fluid communication with the gas supply, a second vacuum pump, a second manometer, and an inlet of the vacuum chamber, wherein a fourth isolation valve is located between the second liquid supply and the gas supply and a fifth isolation valve is located between the second liquid supply and the inlet of the vacuum chamber;
wherein the first liquid supply can receive liquid from the chamber when the first isolation valve is in an open position, the first liquid supply can deliver liquid to the second liquid supply when the second isolation valve is in an open position, and wherein a pressure differential between the second liquid supply and the chamber can force the liquid through a filter to the chamber when the pressure differential is great enough to overcome the force of gravity in the second liquid supply.

11. A method of forming a flowing protective liquid layer on a plasma exposed surface of a chamber wall in a plasma processing apparatus while processing a semiconductor substrate in a vacuum chamber, the method comprising supplying plasma compatible liquid from a liquid supply to a portion of the chamber wall and flowing the liquid over the plasma exposed surface of the chamber wall to form a flowing protective liquid layer on the plasma exposed surface thereof while plasma processing the semiconductor substrate in the vacuum chamber.

12. The method of claim 11, further comprising
(a) controlling a pressure differential between the liquid supply and the vacuum chamber such that the pressure differential between the liquid supply and the vacuum chamber forces the liquid in liquid feed passages in the chamber wall towards the plasma exposed surface, wherein the pressure differential forces the liquid towards the plasma exposed surface of the chamber wall such that a predetermined thickness of the flowing protective liquid layer is maintained on the chamber wall during processing of the semiconductor substrate;
(b) pumping the liquid in the liquid supply towards the plasma exposed surface of the chamber wall and maintaining a predetermined thickness of the liquid layer flowing over the plasma exposed surface during processing of the semiconductor substrate; or
(c) controlling a pressure differential between the liquid supply and the vacuum chamber such that the pressure differential between the liquid supply and the vacuum chamber forces the liquid in a distribution channel in the chamber wall to overflow onto the plasma exposed surface thereof, wherein the pressure differential overflows the liquid onto the plasma exposed surface of the chamber wall such that a predetermined thickness of the flowing protective liquid layer is maintained on the chamber wall during processing of the semiconductor substrate.

13. The method of claim 11, wherein
(a) the plasma compatible liquid is flowed over the plasma exposed surface of the chamber wall such that the flowing protective liquid layer has a thickness of about 1 to 5,000 microns;
(b) the plasma compatible liquid is flowed over the plasma exposed surface of the chamber wall such that the flowing protective liquid layer has a thickness of about 100 microns or greater;
(c) the plasma compatible liquid is supplied to microgrooves in the plasma exposed surface of the chamber wall such that the liquid supplied to the plasma exposed surface of the chamber wall is channeled by the microgrooves and forms a continuous flowing protective liquid layer;
(d) the plasma compatible liquid is a flowable oxide precursor;
(e) the plasma compatible liquid is an ionic fluid;
(f) the plasma compatible liquid has a vapor pressure below about 10⁻⁶ torr at about 20° C.;
(g) the plasma compatible liquid is a perfluoropolyether;
(h) the plasma compatible liquid has a molecular weight of about 800 to 5,000 g/mol; and/or
(i) the plasma compatible liquid has a molecular weight greater than about 1,000 g/mol.

14. The method of claim 11, further including:
(a) maintaining the plasma exposed surface at a controlled temperature by circulating the liquid through a heat exchanger;
(b) circulating the liquid through a filter such that impurities and/or nonvolatile etch byproducts in the liquid resulting from processing the semiconductor substrate are removed; and/or
(c) circulating the liquid through an electrical discharge conduit which removes charge built up in the liquid due to exposure to the plasma.

15. The method of claim 11, wherein the liquid is flowed over the plasma exposed surface at a rate sufficient to offset plasma erosion of the flowing protective liquid layer during plasma processing of the semiconductor substrate.

16. The method of claim 11, wherein the liquid is continuously supplied to an upper portion of the plasma exposed surface and collected at a lower portion of the plasma exposed surface during plasma processing of the semiconductor substrate wherein the liquid is collected by a liquid collection tray, wherein the liquid collection tray is in fluid communication with the liquid supply such that the liquid may be returned from the vacuum chamber to the liquid supply.

17. The method of claim 11, wherein:
(a) the chamber wall comprises a porous ceramic material and the liquid is supplied to the plasma exposed surface by wicking through the porous ceramic material to the plasma exposed surface;
(b) the liquid is supplied to the plasma exposed surface by wicking through capillary sized holes in the chamber wall; or
(c) the chamber wall comprises a distribution channel and the liquid is supplied to the plasma exposed surface by overflowing from the distribution channel.

18. The method of claim 11, wherein the plasma exposed surface of the chamber wall is
(a) a vertical surface and/or a sloped surface of a chamber wall;
(b) a vertical surface and/or a sloped surface of a chamber liner;
(c) a vertical surface and/or a sloped surface of a faraday shield; and/or
(d) an upper plasma exposed surface and/or a lower plasma exposed surface of a faraday shield.

19. The method of claim 11, wherein the liquid is flowed over the plasma exposed surface to a component adjacent the chamber wall and wherein
(a) the liquid is configured to pool on a plasma exposed surface of the adjacent component thereby forming a static protective liquid layer on the plasma exposed surface; or
(b) the liquid is configured to flow over a plasma exposed surface of the adjacent component.

20. A method of plasma processing a semiconductor substrate in the apparatus according to claim 1, comprising:
supplying the plasma compatible liquid from the liquid supply to the chamber wall of the vacuum chamber;
flowing the liquid over the plasma exposed surface of the chamber wall;
supplying the process gas from the process gas source into the plasma processing chamber;
applying RF energy to the process gas using the RF energy source to generate plasma in the plasma processing chamber; and
plasma processing a semiconductor substrate in the plasma processing chamber.
